(19) United States
(12) Patent Application Publication
(10) Pub. No.: US 2018/0097122 A1
(43) Pub. Date: Apr. 5, 2018

(54) THIN FILM TRANSISTOR, MANUFACTURE METHOD OF THIN FILM TRANSISTOR AND CMOS DEVICE

(71) Applicant: Shenzhen China Star Optoelectronics Technology Co., Ltd, Shenzhen, Guangdong (CN)

(72) Inventor: Jinquan DENG, Shenzhen, Guangdong (CN)

(73) Assignee: Shenzhen China Star Optoelectronics Technology Co., Ltd., Shenzhen, Guangdong (CN)

(21) Appl. No.: 15/101,029

(22) PCT Filed: May 9, 2016
(86) PCT No.: PCT/CN2016/081458

§ 371 Date: Jun. 2, 2016

(30) Foreign Application Priority Data
Apr. 18, 2016 (CN) 201610242557.5

(51) Int. Cl. H01L 29/786; H01L 29/10; H01L 29/66

(52) U.S. Cl. CPC H01L 29/78675; H01L 2029/7863; H01L 29/66757; H01L 29/1041

(57) ABSTRACT

A thin film transistor, a manufacture method of a thin film transistor and a CMOS device are provided. The thin film transistor includes: a substrate and a low temperature poly-silicon (LTPS) layer disposed on the same side of the substrate, a first and a second light doped zones disposed adjacently to two opposite ends of the LTPS on the same layer with the LTPS, a first heavy doped zone disposed on the same layer with the LTPS, the first heavy doped zone is disposed adjacently to an end of the first light doped zone away from the LTPS, the second heavy doped zone is disposed adjacently to an end of the second light doped zone away from the LTPS, the first insulating layer, covering the first and the second light doped zones as well as the first and the second heavy doped zones.

### CROSS REFERENCE

This disclosure claims priority to patent application No. 201610242557.5 filed Apr. 18, 2016 and entitled ‘Thin film transistor, manufacture method of thin film transistor and CMOS device’, the above application is incorporated in the disclosure by reference.

### FIELD OF THE DISCLOSURE

The disclosure relates to a display field, and more particularly to a thin film transistor, a manufacture method of a thin film transistor and a CMOS device.

### BACKGROUND OF THE DISCLOSURE

A display, such as a liquid crystal display (LCD), is a commonly used electronic device, preferred by customers due to properties like low energy consumption, small volume and lightweight. A demand of a LCD with high resolution and low energy consumption is proposed according to the development of a flat display technique. Electron mobility of amorphous silicon is low, low temperature poly-silicon (LTPS) with higher carrier mobility compared with amorphous silicon can be produced under low temperature. Next, a CMOS device made of LTPS can be applied in a LCD so that the LCD can obtain higher resolution and lower energy consumption. Therefore, LTPS is widely applied and studied. Higher carrier mobility can cause a hot carrier effect easily, leading to a threshold voltage (Vth) of a low temperature poly-silicon thin film transistor with LTPS drifts or a Kink effect, etc. A light doped transition zone such as a light doped drain (LDD) or a gate on LDD (GOLDD) is formed by ion implantation to prevent the hot carrier effect. Formation of the light doped transition zone can be a mask process or a gate self alignment doping. Shortcomings of the processes are too many mask processes required, and a doping deviation in the formed low temperature poly-silicon thin film transistor can occur easily or the gate drifts away from the LDD zone, resulting in a poor performance of a device with a low temperature poly-silicon thin film transistor.

### SUMMARY OF THE DISCLOSURE

The disclosure provides a thin film transistor, the thin film transistor includes: a substrate; a low temperature poly-silicon layer disposed adjacently to a surface of the substrate; a first light doped zone and a second light doped zone, disposed on the same layer with the low temperature poly-silicon layer, and disposed adjacently to two opposite ends of the low temperature poly-silicon layer, doping concentration of the first light doped zone and that of the second light doped zone symmetrical to the low temperature poly-silicon layer are identical; a first heavy doped zone and a second heavy doped zone, disposed on the same layer with the low temperature poly-silicon layer, the first heavy doped zone is disposed adjacently to an end of the first light doped zone away from the low temperature poly-silicon layer, the second heavy doped zone is disposed adjacently to an end of the second light doped zone away from the low temperature poly-silicon layer, doping concentration of the first light doped zone and that of the second light doped zone symmetrical to the low temperature poly-silicon layer are identical, doping types of the first light doped zone, the second light doped zone, the first heavy doped zone and the second heavy doped zone are identical; a first insulating layer covers the first light doped zone, the second light doped zone, the first heavy doped zone and the second heavy doped zone, distances from a surface of the first insulating layer away from the substrate to a surface of the first light doped zone away from the substrate, a surface of the second light doped zone away from the substrate, a surface of the first heavy doped zone away from the substrate and a surface of the second heavy doped zone away from the substrate are identical; a gate, the gate includes a first surface, a second surface and a third surface, the first surface is disposed on a surface of the first insulating layer away from the substrate, the second surface and the third surface are disposed opposite, the second surface and the first surface intersect, the second surface, compared with the third surface, is disposed closer to the first light doped zone, the third surface and the first surface intersect, a distance of a flat surface where the second surface is and a flat surface where the first light doped zone and the low temperature poly-silicon layer are connected is identical to that of a flat surface where the third surface is and a flat surface where the second light doped zone and the low temperature poly-silicon layer are connected.

The flat surface where the second surface is disposed between the surface where the first light doped zone and the low temperature poly-silicon layer are connected and the surface where the first light doped zone and the first heavy doped zone are connected, the flat surface where the third surface is disposed between the surface where the second light doped zone and the low temperature poly-silicon layer are connected and the surface where the second light doped zone and the second heavy doped zone are connected.

A first through-hole and a second through-hole are defined in the first insulating layer, the first through-hole corresponds to the first heavy doped zone, the second through-hole corresponds to the second heavy doped zone, the thin film transistor further includes: a second insulating layer, covering the gate, a third through-hole and a fourth through-hole are defined in the second insulating layer, the third through-hole and the first through-hole are connected, the fourth through-hole and the second through-hole are connected; a source electrode and a drain electrode, disposed on the second insulating layer separately, the source electrode and the first heavy doped zone are connected through the first through-hole and the third through-hole, the drain electrode and the second heavy doped zone are connected through the second through-hole and the fourth through-hole; the thin film transistor further includes: a flat layer and a pixel electrode, covering the source electrode and the drain electrode, and a fifth through-hole is defined in the flat layer, the fifth through-hole is disposed correspondingly to the drain electrode, the pixel electrode is disposed on the flat layer and connected to the drain electrode through the fifth through-hole.

The doping types of the first light doped zone, the second light doped zone, the first heavy doped zone and the second heavy doped zone are identically N type ion doping or identically P type ion doping.

The disclosure further provides a manufacture method of a thin film transistor, the manufacture method of a thin film transistor includes: providing a substrate; forming a low temperature poly-silicon material layer on a surface of the substrate and patterning the low temperature poly-silicon material layer, to form a low temperature poly-silicon pattern; disposing a first insulating layer, a first metal layer and a first light block layer on a surface of the low temperature poly-silicon pattern away from the substrate in sequence; patterning the first light block layer, to expose two ends of the first metal layer, the patterned first light block layer is a first light block pattern, solidifying the first light block pattern, the first light block pattern includes a first section and a second section, the first section is disposed on the middle of the first metal layer, the second section is disposed on a surface of the first section away from the first metal layer, the first section and the second section form a convexity; patterning the first metal layer, merely remaining a part of the first metal layer covered by the first section and the second section simultaneously, the remaining first metal layer forms a gate of the thin film transistor; partially ashing a part of the first section without being covered by the second section and totally ashing the second section, the pattern of the first section after being partially ashed is a second light block pattern, the second light block pattern includes a first subsection and a second subsection, the first subsection is disposed on the gate, the second subsection is disposed on a surface of the first subsection away from the gate, and a width of the second subsection is less than that of the first subsection, the first subsection and the second subsection form a convexity, and the width of the second subsection is less than that of the gate; ions doping the low temperature poly-silicon pattern with applying the second light block pattern and the first insulating layer as masks, a low temperature poly-silicon pattern corresponding to the gate forms a low temperature poly-silicon layer, a low temperature poly-silicon pattern corresponding to the first subsection instead of the second subsection forms a first light doped zone and a second light doped zone, an end of the first light doped zone away from the low temperature poly-silicon layer forms a first heavy doped zone, an end of the second light doped zone away from the low temperature poly-silicon layer forms a second heavy doped zone; removing the second light block pattern.

The manufacture method of a thin film transistor further includes: depositing a second insulating layer on the gate and the first insulating layer; defining through-holes in the second insulating layer and the first insulating layer corresponding to the first heavy doped zone and the second heavy doped zone, to form a first through-hole corresponding to the first heavy doped zone and a second through-hole corresponding to the second heavy doped zone in the first insulating layer, to form a third through-hole connected to the first through-hole and a fourth through-hole connected to the second through-hole in the second insulating layer; depositing a second metal layer on the second insulating layer, patterning the second metal pattern, to form a source electrode connected to the first heavy doped zone through the first through-hole and the third through-hole, and a drain electrode connected to the second heavy doped zone through the second through-hole and the fourth through-hole; depositing a flat layer on the source electrode and the drain electrode.

The ion doping is N type ion doping or P type ion doping.

When the low temperature poly-silicon pattern is ion doped with the second light block pattern and the first insulating layer as masks, concentration of doped ions of the corresponding first section, the corresponding second section and the first light block pattern are identical, times for doping are identical.

The disclosure further provides a CMOS device, the CMOS device includes a thin film transistor in any above-described embodiments.

The low temperature poly-silicon pattern is ion doped with the second light block pattern and the first insulating layer as masks in the manufacture method of a thin film transistor of the disclosure, various ion concentration doped in each section of the low temperature poly-silicon pattern can be achieved by utilizing a width of the second light block pattern and that of the first insulating layer. Equally, the low temperature poly-silicon pattern corresponding to the gate forms a low temperature poly-silicon layer, the low temperature poly-silicon pattern corresponding to the first subsection instead of the second subsection forms a first light doped zone and a second light doped zone, an end of the first light doped zone away from the low temperature poly-silicon layer forms a first heavy doped zone, an end of the second light doped zone away from the low temperature poly-silicon layer forms a second heavy doped zone. A mask process is unnecessary in the step, which can simplify a manufacture process of a thin film transistor.

### BRIEF DESCRIPTION OF THE DRAWINGS

In order to more clearly illustrate the embodiments of the disclosure or prior art, embodiments or figures described in prior art will be briefly introduced, it is obvious that the drawings are merely some embodiments of the disclosure, a person skilled in the art can obtain other figures according to these figures without creative work.

FIG. 1 is a schematic, cross-sectional structure view of a thin film transistor according to a preferred embodiment of the disclosure.

FIG. 2 is a circuit schematic view of a CMOS device according to a preferred embodiment of the disclosure.

FIG. 3 is a schematic, cross-sectional structure view of a CMOS device according to a preferred embodiment of the disclosure.

FIG. 4 is a flow chart of a manufacture method of a thin film transistor according to a preferred embodiment of the disclosure.

FIG. 5 through FIG. 12 are structural views corresponding to each step of a manufacture method of a thin film transistor according to the disclosure.

### DETAILED DESCRIPTION OF PREFERRED EMBODIMENTS

Technical proposals according to embodiments of the disclosure will be described in detail with reference to the accompanying drawings as follows, it is clear that the described embodiments are merely part of embodiments of the disclosure rather than all embodiments. Based on the embodiments of the disclosure, all other embodiments obtained by a person skilled in the art without paying creative efforts should be considered within the scope of protection of the disclosure.

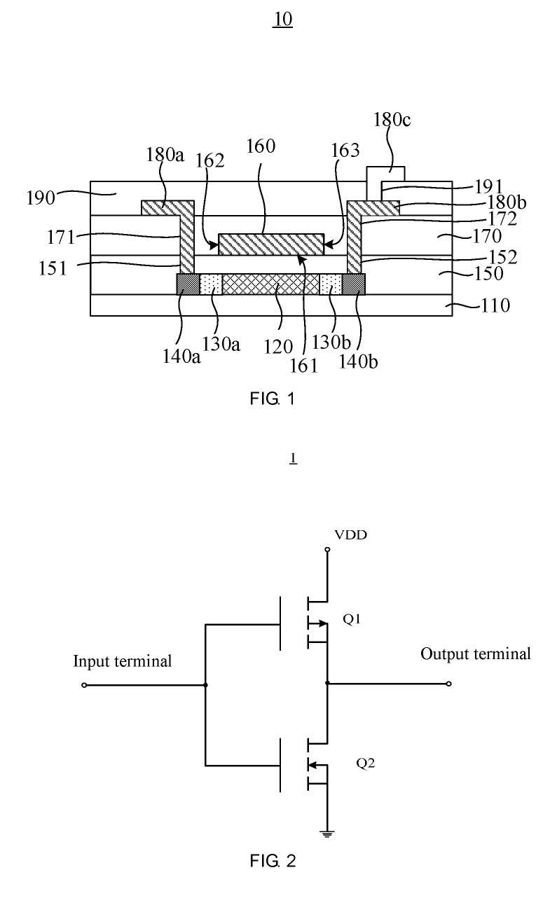

Referring to FIG. 1, FIG. 1 is a schematic, cross-sectional structure view of a thin film transistor according to a preferred embodiment of the disclosure. The thin film transistor 10 includes a substrate 110, a low temperature poly-silicon layer 120, a first light doped zone 130a, a second light doped zone 130b, a first heavy doped zone 140a, a second heavy doped zone 140b, a first insulating layer 150 and a gate 160. The low temperature poly-silicon layer 120, the first light doped zone 130a, the second light doped zone 130b, the first heavy doped zone 140a, the second heavy doped zone 140b, the first insulating layer 150 and the gate 160 are disposed adjacently to the substrate 110. The first light doped zone 130a and the second light doped zone 130b are disposed on the same layer with the low temperature poly-silicon layer 120, and disposed adjacently to two opposite ends of the low temperature poly-silicon layer 120, doping concentration of the first light doped zone 130a and that of the second light doped zone 130b symmetrical to the low temperature poly-silicon layer 120 are identical. The first heavy doped zone 140a and the second heavy doped zone 140b are disposed on the same layer with the low temperature poly-silicon layer 120, the first heavy doped zone 140a is disposed adjacently to an end of the first light doped zone 130a away from the low temperature poly-silicon layer 120, the second heavy doped zone 140b is disposed adjacently to an end of the second light doped zone 130b away from the low temperature poly-silicon layer 120, doping concentration of the first heavy doped zone 140a and that of the second heavy doped zone 140b symmetrical to the low temperature poly-silicon layer 120 are identical. Doping types of the first light doped zone 130a, the second light doped zone 130b, the first heavy doped zone 140a and the second heavy doped zone 140b are identical. The first insulating layer 150 covers the first light doped zone 130a, the second light doped zone 130b, the first heavy doped zone 140a and the second heavy doped zone 140b, distances from a surface of the first insulating layer 150 away from the substrate 110 to surfaces away from the substrate 110 of the first light doped zone 130a, the second light doped zone 130b, the first heavy doped zone 140a and the second heavy doped zone 140b are identical. In other words, distances from a surface of the first insulating layer 150 away from the substrate 110 to a surface of the first light doped zone 130a away from the substrate 110, a surface of the second light doped zone 130b away from the substrate 110, a surface of the first heavy doped zone 140a away from the substrate 110 and a surface of the second heavy doped zone 140b away from the substrate 110 are identical. The gate 160 includes a first surface 161, a second surface 162 and a third surface 163. The first surface 161 is disposed on a surface of the first insulating layer 150 away from the substrate 110, the second surface 162 and the third surface 163 are disposed opposite, the second surface 162, compared with the third surface 163, is disposed closer to the first light doped zone 130a, the third surface 163 and the first surface 161 intersect, a distance of a flat surface where the second surface 162 is and a flat surface where the first light doped zone 130a and the low temperature poly-silicon layer 120 are connected is identical to that of a flat surface where the third surface 163 is and a flat surface where the second light doped zone 130b and the low temperature poly-silicon layer 120 are connected.

A distance of a flat surface where the second surface 162 is and a flat surface where the first light doped zone 130a and the low temperature poly-silicon layer 120 are connected is identical to that of a flat surface where the third surface 163 is and a flat surface where the second light doped zone 130b and the low temperature poly-silicon layer 120 are connected, in other words, the surface where the first light doped zone 130a and the low temperature poly-silicon 120 are connected is a first flat surface, the distance of the surface where the second surface 162 is and the first flat surface is a first distance. The surface where the second light doped zone 130b and the low temperature poly-silicon layer 120 are connected is a second flat surface, the distance of the surface where the third surface 163 is and the second flat surface is a second distance, the second distance equals to the first distance.

A material of the substrate 110 includes an electrical insulating material such as one or more of quartz, mica, aluminum oxide or transparent plastic, etc. The substrate 110 is an insulating base that can reduce high frequency loss of the substrate 110.

The low temperature poly-silicon layer 120, the first light doped zone 130a, the second light doped zone 130b, the first heavy doped zone 140a, the second heavy doped zone 140b, the first insulating layer 150 and the gate 160 are disposed on the same side of the substrate 110. Similarly, the low temperature poly-silicon layer 120, the first light doped zone 130a, the second light doped zone 130b, the first heavy doped zone 140a, the second heavy doped zone 140b, the first insulating layer 150 and the gate 160 can be disposed on the same side of the substrate 110 directly or indirectly. In another embodiment, the low temperature poly-silicon layer 120, the first light doped zone 130a, the second light doped zone 130b, the first heavy doped zone 140a, the second heavy doped zone 140b, the first insulating layer 150 and the gate 160 can be disposed on the same side of the substrate 110 by a buffer layer. The buffer layer can reduce damage to the substrate 110 in manufacturing the thin film transistor 10.

The flat surface where the second surface 162 is located between the flat surface where the first light doped zone 130a and the low temperature poly-silicon layer 120 are connected and the flat surface where the first light doped zone 130a and the first heavy zone 140a are connected. The flat surface where the third surface 163 is located between the flat surface where the second light doped zone 130b and the low temperature poly-silicon layer 120 are connected and the flat surface where the second light doped zone 130b and the second heavy zone 140b are connected.

A first through-hole 151 and a second through-hole 152 are defined in the first insulating layer 150. The first through-hole 151 corresponds to the first heavy doped zone 140a, the second through-hole 151 corresponds to the second heavy doped zone 140b. The thin film transistor 10 further includes a second insulating layer 170, a source electrode 180a and a drain electrode 180b. The second insulating layer 170 covers the gate 160, a third through-hole 171 and a fourth through-hole 172 are defined in the second insulating layer 170. The third through-hole 171 and the first through-hole 151 are connected, the fourth through-hole 172 and the second through-hole 152 are connected. The source electrode 180a and the drain electrode 180b are disposed on the second insulating layer 170 separately, the source electrode 180a and the first heavy doped zone 140a are connected through the first through-hole 151 and the third through-hole 171, the drain electrode 180b and the second heavy doped zone 140b are connected through the second through-hole 152.

The thin film transistor 10 further includes a flat layer 190 and a pixel electrode 180c. The flat layer 190 covers the source electrode 180a and the drain electrode 180b, a fifth through-hole 191 is defined in the flat layer 190, the fifth through-hole 191 is disposed correspondingly to the drain electrode 180b. The pixel electrode 180c is disposed on the flat layer 190 and connected to the drain electrode 180b through the fifth through-hole 191.

Doping types of the first light doped zone 130a, the second light doped zone 130b, the first heavy doped zone 140a and the second heavy doped zone 140b are identically N type ion doping or identically P type ion doping. Ions of the N type ion doping can be phosphorus (P) ions and arsenic (AS) ions, which can be gone far beyond. Ions of the P type ion doping can be boron (B) ions, which can be gone far beyond.

Doping concentration of the first heavy doped zone 140a is more than that of the first light doped zone 130a. Doping concentration of the second heavy doped zone 140b is more than that of the second light doped zone 130b. Doping concentration of the first heavy doped zone 140a being more than that of the first light doped zone 130a and doping concentration of the second heavy doped zone 140b being more than that of the second light doped zone 130b according to the embodiment can reduce contact resistance between the source electrode 180a and the low temperature poly-silicon layer 120 and reduce contact resistance between the drain electrode 180b and the low temperature poly-silicon layer 120, as well as reducing leakage current of the thin film transistor 10.

The first insulating layer 150 includes but not limit to silicon nitride (SiNx) or silicon oxide (SiOx).

A material of the gate 160 includes but not limit to one or more of metal materials such as Al, Mo, Cu, Ag, Cr, Ti, AlNi, MoTi. A thickness of the gate 160 is 1500-6000 angstroms.

The second insulating layer 170 includes but not limit to silicon nitride (SiNx) or silicon oxide (SiOx).

Materials of the source electrode 180a and the drain electrode 180b include but not limit to one or more of metal materials such as Al, Mo, Cu, Ag, Cr, Ti, AlNi, MoTi.

The pixel electrode 180c can include but not limit to one or more of following materials: a ZnO based transparent oxide semiconductor material, a SnO₂ based transparent oxide semiconductor material, an In₂O₃ based transparent oxide semiconductor material, etc. For instance, the transparent oxide semiconductor film can be indium gallium zinc oxide (IGZO).

The first light doped zone 130a and the second light doped zone 130b are disposed on the same layer with the low temperature poly-silicon layer 120, and disposed adjacently to two opposite ends of the low temperature poly-silicon layer 120, doping concentration of the first light doped zone 130a and that of the second light doped zone 130b symmetrical to the low temperature poly-silicon layer 120 are identical; a first heavy doped zone 140a and a second heavy doped zone 140b are disposed on the same layer with the low temperature poly-silicon layer 120, the first heavy doped zone 140a is disposed adjacently to an end of the first light doped zone 130a away from the low temperature poly-silicon layer 120, the second heavy doped zone 140b is disposed adjacently to an end of the second light doped zone 130b away from the low temperature poly-silicon layer 120, doping concentration of the first heavy doped zone 140a and that of the second heavy doped zone 140b symmetrical to the low temperature poly-silicon layer 120 are identical; the gate 160 includes the first surface 161, the second surface 162 and the third surface 163. The first surface 161 is disposed on a surface of the first insulating layer 150 away from the substrate 110, the second surface 162 and the third surface 163 are disposed opposite, the second surface 162, compared with the third surface 163, is disposed closer to the first light doped zone 130a, the third surface 163 and the first surface 161 intersect, a distance of a flat surface where the second surface 162 is and a flat surface where the first light doped zone 130a and the low temperature poly-silicon layer 120 are connected is identical to that of a flat surface where the third surface 163 is and a flat surface where the second light doped zone 130b and the low temperature poly-silicon layer 120 are connected, which can make a threshold voltage of the thin film transistor 10 stable, in order to improve electrical properties of the thin film transistor 10.

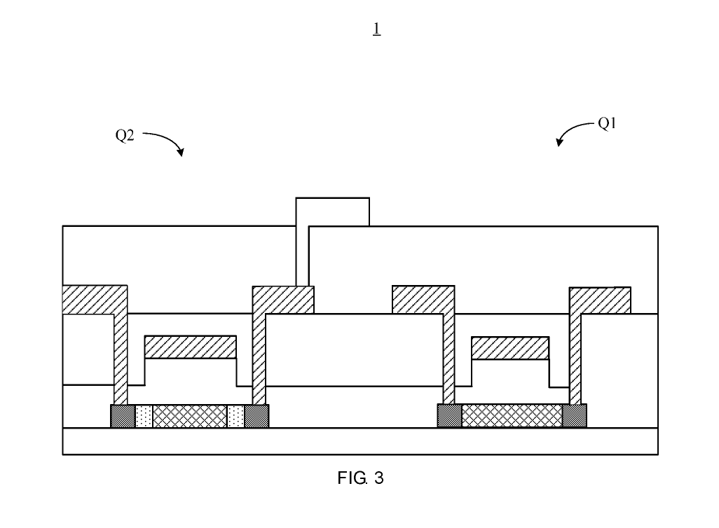

The disclosure further provides a complementary metal oxide semiconductor (CMOS) device 1, referring to FIG. 2 and FIG. 3. FIG. 2 is a circuit schematic view of a CMOS device according to a preferred embodiment of the disclosure; FIG. 3 is a schematic, cross-sectional structure view of a CMOS device according to a preferred embodiment of the disclosure. The CMOS device 1 includes a first thin film transistor Q1 and a second thin film transistor Q2, when the first thin film transistor Q1 is a N type thin film transistor, the second thin film transistor Q2 is a P type thin film transistor, when the first thin film transistor Q1 is a P type thin film transistor, the second thin film transistor Q2 is a N type thin film transistor. A gate of the first thin film transistor Q1 is connected to a gate of the second thin film transistor Q2 electrically, a drain electrode of the first thin film transistor Q1 is connected to a source electrode of the second thin film transistor Q2. The first thin film transistor Q1 in the CMOS device according to the embodiment can be the above-described thin film transistor 10, or the second thin film transistor Q2 in the CMOS device is the above-described thin film transistor 10, repeated description is ignored here.

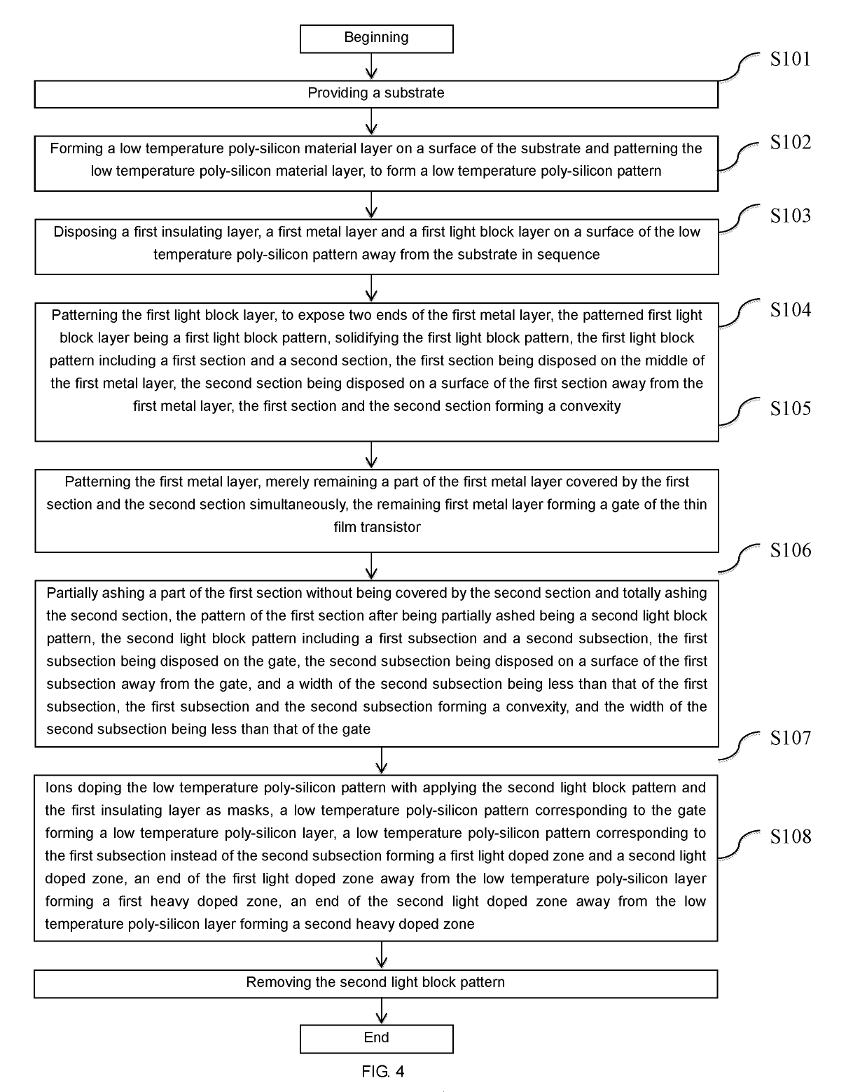

A manufacture method of a thin film transistor of the disclosure will be introduced referring to FIG. 1 and description of the thin film transistor 10 as follows. Referring to FIG. 4, FIG. 4 is a flow chart of a manufacture method of a thin film transistor according to a preferred embodiment of the disclosure. The manufacture method of a thin film transistor includes but not limit to following steps.

S101, providing a substrate 110. A material of the substrate 110 includes an electrical insulating material such as one or more of quartz, mica, aluminum oxide or transparent plastic, etc. The substrate 110 is an insulating layer base that can reduce high frequency loss of the substrate 110.

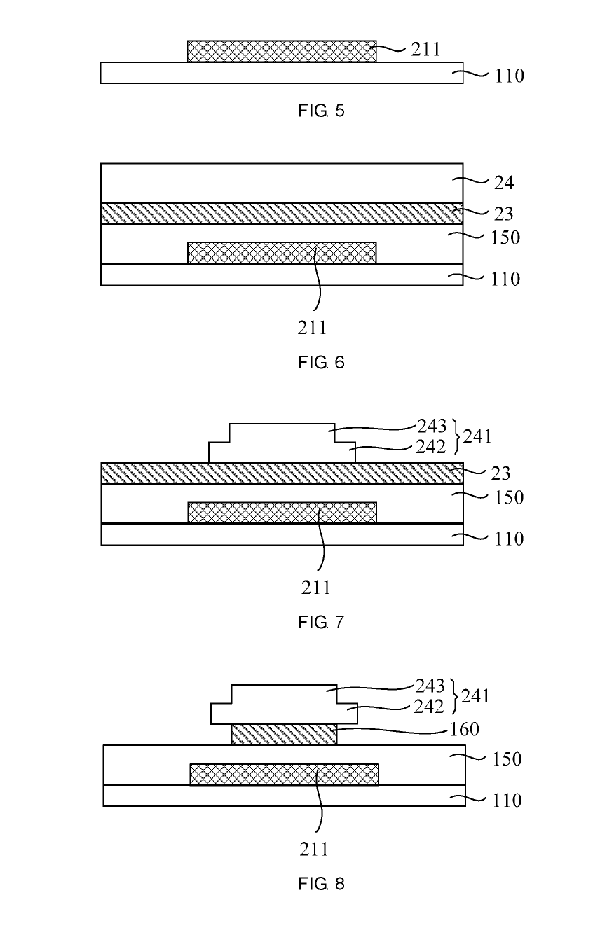

S102, forming a low temperature poly-silicon material layer on a surface of the substrate 110 and patterning the low temperature poly-silicon material layer, to form a low temperature poly-silicon pattern 211. Referring to FIG. 5 as well, in other embodiments, forming an amorphous silicon layer on a surface of the substrate 110 and treating the amorphous silicon layer with excimer laser annealing or other methods can turn amorphous silicon in the amorphous silicon layer to poly-silicon as well.

S103, disposing a first insulating layer 150, a first metal layer 23 and a first light block layer 24 on a surface of the low temperature poly-silicon pattern 211 away from the substrate 110 in sequence. FIG. 6 can be referred as well.

S104, patterning the first light block layer 24, to expose two ends of the first metal layer 23, the patterned first light block layer 24 is a first light block pattern 241, solidifying the first light block pattern 241, the first light block pattern 241 includes a first section 242 and a second section 243, the first section 242 is disposed on the middle of the first metal layer 23, the second section 243 is disposed on a surface of the first section 242 away from the first metal layer 23, the first section 242 and the second section 243 form a convexity. FIG. 7 can be referred as well.

S105, patterning the first metal layer 23, merely remaining a part of the first metal layer 23 covered by the first section 242 and the second section 243 simultaneously, the remaining first metal layer 23 forms the gate 160 of the thin film transistor 10. FIG. 8 can be referred as well.

S106, partially ashing a part of the first section 242 without being covered by the second section 243 and totally ashing the second section 243, the pattern of the first section 242 after being partially ashed is a second light block pattern 243a, the second light block pattern 243a includes a first subsection 2431 and a second subsection 2432, the first subsection 2431 is disposed on the gate 160, the second subsection 2432 is disposed on a surface of the first subsection 2431 away from the gate 160, and a width of the second subsection 2432 is less than that of the first subsection 2431, the first subsection 2431 and the second subsection 2432 form a convexity, and the width of the second subsection 2432 is equal to that of the gate 160. FIG. 9 is referred as well.

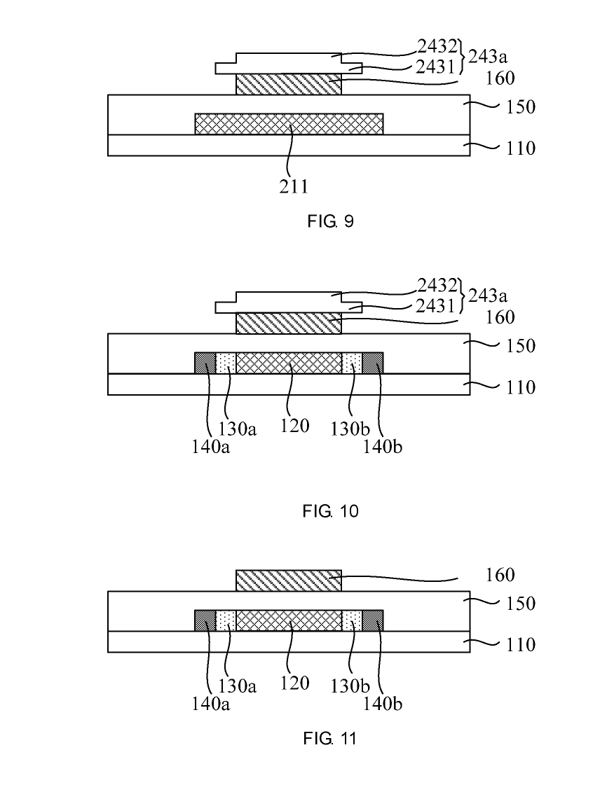

S107, ions doping the low temperature poly-silicon pattern 211 with applying the second light block pattern 243a and the first insulating layer 150 as masks, the low temperature poly-silicon pattern 211 corresponding to the gate 160 forms the low temperature poly-silicon layer 120, the low temperature poly-silicon pattern 211 corresponding to the first subsection 2431 instead of the second subsection 2432 forms a first light doped zone 130a and a second light doped zone 130b, an end of the first light doped zone 130a away from the low temperature poly-silicon layer 211 forms the first heavy doped zone 140a, an end of the second light doped zone 130b away from the low temperature poly-silicon layer 120 forms the second heavy doped zone 140b. FIG. 10 can be referred as well.

S108, removing the second light block pattern 243a. FIG. 11 can be referred as well.

The low temperature poly-silicon pattern 211 is ion doped with the second light block pattern 243a and the first insulating layer 150 as masks in the manufacture method of a thin film transistor of the disclosure, various ion concentration doped in each section of the low temperature poly-silicon pattern 211 can be achieved by utilizing a thickness of the second light block pattern 243a and that of the first insulating layer 150. Equally, the low temperature poly-silicon pattern 211 corresponding to the gate 160 forms a low temperature poly-silicon layer 120, the low temperature poly-silicon pattern 211 corresponding to the first subsection 2431 instead of the second subsection 2432 forms a first light doped zone 130a and a second light doped zone 130b, an end of the first light doped zone 130a away from the low temperature poly-silicon layer 211 forms a first heavy doped zone 140a, an end of the second light doped zone 130b away from the low temperature poly-silicon layer 120 forms a second heavy doped zone 140b. A mask process is unnecessary in the step, which can simplify a manufacture process of a thin film transistor.

The manufacture method of the thin film transistor further includes following steps.

S109, depositing a second insulating layer 170 on the gate 160 and the first insulating layer 150.

S110, defining through-holes in the second insulating layer 170 and the first insulating layer 150 corresponding to the first heavy doped zone 140a and the second heavy doped zone 140b, to form a first through-hole 151 corresponding to the first heavy doped zone 140a and a second through-hole 152 corresponding to the second heavy doped zone 140b in the first insulating layer 150, and to form a third through-hole 171 connected to the first through-hole 151 and a fourth through-hole 172 connected to the second through-hole 152 in the second insulating layer 170.

S111, depositing a second metal layer on the second insulating layer 170, patterning the second metal pattern, to form a source electrode 180a connected to the first heavy doped zone 140a through the first through-hole 151 and the third through-hole 171, and a drain electrode 180b connected to the second heavy doped zone 140b through the second through-hole 152 and the fourth through-hole 172.

S112, depositing a flat layer 190 on the source electrode 180a and the drain electrode 180b.

The manufacture method of a thin film transistor further includes following steps.

Step S113, defining a fifth through-hole 191 in the flat layer 190 corresponding to the drain electrode 180b.

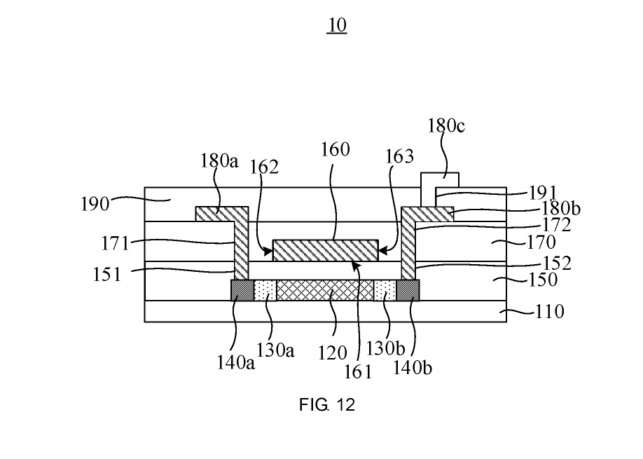

Step S114, depositing a transparent conductive layer on the flat layer 190, patterning the transparent conductive layer, to form a pixel electrode 180c connected to the drain electrode 180b through the fifth through-hole 191. Step S109˜step S114 refer to FIG. 12.

Above are preferred embodiments of the disclosure, which does not limit the scope of the disclosure, a person skilled in the art can understand all or portion of the processes in the method according to the aforesaid embodiments and modifications, equivalent replacements or improvements within the spirit and principles of the embodiments described above should be covered by the protected scope of the disclosure.

What is claimed is:

1. A thin film transistor, wherein the thin film transistor comprises:
a substrate;
a low temperature poly-silicon layer disposed adjacently to a surface of the substrate;
a first light doped zone and a second light doped zone, disposed on the same layer with the low temperature poly-silicon layer, and disposed adjacently to two opposite ends of the low temperature poly-silicon layer, doping concentration of the first light doped zone and that of the second light doped zone symmetrical to the low temperature poly-silicon layer being identical;
a first heavy doped zone and a second heavy doped zone, disposed on the same layer with the low temperature poly-silicon layer, the first heavy doped zone being disposed adjacently to an end of the first light doped zone away from the low temperature poly-silicon layer, the second heavy doped zone being disposed adjacently to an end of the second light doped zone away from the low temperature poly-silicon layer, doping concentration of the first heavy doped zone and that of the second heavy doped zone symmetrical to the low temperature poly-silicon layer being identical, and doping types of the first light doped zone, the second light doped zone, the first heavy doped zone and the second heavy doped zone being identical;
a first insulating layer, covering the first light doped zone, the second light doped zone, the first heavy doped zone and the second heavy doped zone, distances from a surface of the first insulating layer away from the substrate to a surface of the first light doped zone away from the substrate, a surface of the second light doped zone away from the substrate, a surface of the first heavy doped zone away from the substrate and a surface of the second heavy doped zone away from the substrate being identical;
a gate, the gate comprising a first surface, a second surface and a third surface, the first surface being disposed on a surface of the first insulating layer away from the substrate, the second surface and the third surface being disposed opposite, the second surface and the first surface intersecting, the second surface, compared with the third surface, being disposed closer to the first light doped zone, the third surface and the first surface intersecting, a distance of a flat surface where the second surface is and a flat surface where the first light doped zone and the low temperature poly-silicon layer are connected being identical to that of a flat surface where the third surface is and a flat surface where the second light doped zone and the low temperature poly-silicon layer are connected.

2. The thin film transistor according to claim 1, wherein the flat surface where the second surface is disposed between the surface where the first light doped zone and the low temperature poly-silicon layer are connected and the surface where the first light doped zone and the first heavy doped zone are connected, the flat surface where the third surface is disposed between the surface where the second light doped zone and the low temperature poly-silicon layer are connected and the surface where the second light doped zone and the second heavy doped zone are connected.

3. The thin film transistor according to claim 1, wherein a first through-hole and a second through-hole are defined in the first insulating layer, the first through-hole corresponds to the first heavy doped zone, the second through-hole corresponds to the second heavy doped zone, the thin film transistor further comprises:
a second insulating layer, covering the gate, a third through-hole and a fourth through-hole being defined in the second insulating layer, the third through-hole and the first through-hole being connected, the fourth through-hole and the second through-hole being connected;
a source electrode and a drain electrode, disposed on the second insulating layer separately, the source electrode and the first heavy doped zone being connected through the first through-hole and the third through-hole, the drain electrode and the second heavy doped zone being connected through the second through-hole and the fourth through-hole.

4. The thin film transistor according to claim 3, wherein the thin film transistor further comprises: a flat layer and a pixel electrode, covering the source electrode and the drain electrode, and a fifth through-hole is defined in the flat layer, the fifth through-hole is disposed correspondingly to the drain electrode, the pixel electrode is disposed on the flat layer and connected to the drain electrode through the fifth through-hole.

5. The thin film transistor according to claim 1, wherein doping types of the first light doped zone, the second light doped zone, the first heavy doped zone and the second heavy doped zone are identically N type ion doping or identically P type ion doping.

6. A manufacture method of a thin film transistor, wherein the manufacture method of a thin film transistor comprises:
providing a substrate;
forming a low temperature poly-silicon material layer on a surface of the substrate and patterning the low temperature poly-silicon material layer, to form a low temperature poly-silicon pattern;
disposing a first insulating layer, a first metal layer and a first light block layer on a surface of the low temperature poly-silicon pattern away from the substrate in sequence;
patterning the first light block layer, to expose two ends of the first metal layer, the patterned first light block layer being a first light block pattern, solidifying the first light block pattern, wherein the first light block pattern comprises a first section and a second section, the first section is disposed on the middle of the first metal layer, the second section is disposed on a surface of the first section away from the first metal layer, the first section and the second section form a convexity;
patterning the first metal layer, merely remaining a part of the first metal layer covered by the first section and the second section simultaneously, the remaining first metal layer forming a gate of the thin film transistor;
partially ashing a part of the first section without being covered by the second section and totally ashing the second section, the pattern of the first section after being partially ashed being a second light block pattern, the second light block pattern comprising a first subsection and a second subsection, the first subsection being disposed on the gate, the second subsection being disposed on a surface of the first subsection away from the gate, and a width of the second subsection being less than that of the first subsection, the first subsection and the second subsection forming a convexity, and the width of the second subsection being equal to that of the gate;
ions doping the low temperature poly-silicon pattern with applying the second light block pattern and the first insulating layer as masks, a low temperature poly-silicon pattern corresponding to the gate forming a low temperature poly-silicon layer, the low temperature poly-silicon pattern corresponding to the first subsection instead of the second subsection forming a first light doped zone and a second light doped zone, an end of the first light doped zone away from the low temperature poly-silicon layer forming a first heavy doped zone, an end of the second light doped zone away from the low temperature poly-silicon layer forming a second heavy doped zone;
removing the second light block pattern.

7. The manufacture method of a thin film transistor according to claim 6, wherein the manufacture method of a thin film transistor further comprises:
depositing a second insulating layer on the gate and the first insulating layer;
defining through-holes in the second insulating layer and the first insulating layer corresponding to the first heavy doped zone and the second heavy doped zone, to form a first through-hole corresponding to the first heavy doped zone and a second through-hole corresponding to the second heavy doped zone in the first insulating layer, to form a third through-hole connected to the first through-hole and a fourth through-hole connected to the second through-hole in the second insulating layer;
depositing a second metal layer on the second insulating layer, patterning the second metal layer, to form a source electrode connected to the first heavy doped zone through the first through-hole and the third through-hole, and a drain electrode connected to the second heavy doped zone through the second through-hole and the fourth through-hole;
depositing a flat layer on the source electrode and the drain electrode.

8. The manufacture method of a thin film transistor according to claim 6, wherein the ion doping is N type ion doping or P type ion doping.

9. The manufacture method of a thin film transistor according to claim 6, wherein when the low temperature poly-silicon pattern is ion doped with the second light block pattern and the first insulating layer as masks, concentration of doping ions of the corresponding first section, the corresponding second section and the first light block pattern are identical, times for doping are identical.

10. A CMOS device, wherein the CMOS device comprises a thin film transistor, the thin film transistor comprises:
a substrate;
a low temperature poly-silicon layer, disposed adjacently to a surface of the substrate;
a first light doped zone and a second light doped zone, disposed on the same layer with the low temperature poly-silicon layer, and disposed adjacently to two opposite ends of the low temperature poly-silicon layer, doping concentration of the first light doped zone and that of the second light doped zone symmetrical to the low temperature poly-silicon layer being identical;
a first heavy doped zone and a second heavy doped zone, disposed on the same layer with the low temperature poly-silicon layer, the first heavy doped zone being disposed adjacently to an end of the first light doped zone away from the low temperature poly-silicon layer, the second heavy doped zone being disposed adjacently to an end of the second light doped zone away from the low temperature poly-silicon layer, doping concentration of the first heavy doped zone and that of the second heavy doped zone symmetrical to the low temperature poly-silicon layer being identical, and doping types of the first light doped zone, the second light doped zone, the first heavy doped zone and the second heavy doped zone being identical;
a first insulating layer, covering the first light doped zone, the second light doped zone, the first heavy doped zone and the second heavy doped zone, distances from a surface of the first insulating layer away from the substrate to a surface of the first light doped zone away from the substrate, a surface of the second light doped zone away from the substrate, a surface of the first heavy doped zone away from the substrate and a surface of the second heavy doped zone away from the substrate being identical;
a gate, the gate comprising a first surface, a second surface and a third surface, the first surface being disposed on a surface of the first insulating layer away from the substrate, the second surface and the third surface being disposed opposite, the second surface and the first surface intersecting, the second surface, compared with the third surface, being disposed closer to the first light doped zone, the third surface and the first surface intersecting, a distance of a flat surface where the second surface is and a flat surface where the first light doped zone and the low temperature poly-silicon layer are connected being identical to that of a flat surface where the third surface is and a flat surface where the second light doped zone and the low temperature poly-silicon layer are connected.

11. The CMOS device according to claim 10, wherein the flat surface where the second surface is disposed between the surface where the first light doped zone and the low temperature poly-silicon layer are connected and the surface where the first light doped zone and the first heavy doped zone are connected, the flat surface where the third surface is disposed between the surface where the second light doped zone and the low temperature poly-silicon layer are connected and the surface where the second light doped zone and the second heavy doped zone are connected.

12. The CMOS device according to claim 10, wherein a first through-hole and a second through-hole are defined in the first insulating layer, the first through-hole corresponds to the first heavy doped zone, the second through-hole corresponds to the second heavy doped zone, the thin film transistor further comprises:
a second insulating layer, covering the gate, a third through-hole and a fourth through-hole being defined in the second insulating layer, the third through-hole and the first through-hole being connected, the fourth through-hole and the second through-hole being connected;
a source electrode and a drain electrode, disposed on the second insulating layer separately, the source electrode and the first heavy doped zone being connected through the first through-hole and the third through-hole, the drain electrode and the second heavy doped zone being connected through the second through-hole and the fourth through-hole.

13. The CMOS device according to claim 12, wherein the thin film transistor further comprises: a flat layer and a pixel electrode, covering the source electrode and the drain electrode, and a fifth through-hole is defined in the flat layer, the fifth through-hole is disposed correspondingly to the drain electrode, the pixel electrode is disposed on the flat layer and connected to the drain electrode through the fifth through-hole.

14. The CMOS device according to claim 10, wherein the doping types of the first light doped zone, the second light doped zone, the first heavy doped zone and the second heavy doped zone are identically N type ion doping or identically P type ion doping.
